(19) United States
(12) Patent Application Publication
(10) Pub. No.: US 2007/0249153 A1
(43) Pub. Date: Oct. 25, 2007

(54) Chip structure with half-tunneling electrical contact to have one electrical contact formed on inactive side thereof and method for producing the same

(76) Inventor: Wen-Chang Dong, Banciao City (TW)

Correspondence Address: BACON & THOMAS, PLLC, 625 SLATERS LANE, FOURTH FLOOR, ALEXANDRIA, VA, 22314, US

(21) Appl. No.: 11/785,447

(22) Filed: Apr. 18, 2007

(30) Foreign Application Priority Data
Apr. 20, 2006 (TW) 095114186

(51) Int. Cl. H01L 21/44; H01L 21/4763

(52) U.S. Cl. 438/597; 438/667; 438/618

(57) ABSTRACT

A method for producing a chip structure with one electrical contact formed on inactive side thereof includes by pre-forming at least one half-tunneling electrical contact to penetrate a processed substrate prepared for processing a chip, and when finishing processing the chip the half-tunneling electrical contact is without completely penetrated the whole chip, particularly one end of the half-tunneling electrical contact is exposed on the inactive side of the chip and formed as an electrical contact of the chip and the other end of the half-tunneling electrical contact is electrically connected to a circuit formed in the chip; the kind of chip having the half-tunneling electrical contact may provide with various layouts and designs of the electrical contacts to minimize the assembled volume of the chip, and the chips are easily stacked together or assembled into a System-In-Package (SIP) structure.

### BACKGROUND OF THE INVENTION

1. Field of the Invention

The present invention relates to a chip structure having one electrical contact formed on inactive side, and more particularly to a method for producing a chip structure having at least one half-tunneling electrical contact that penetrates a processed substrate of the chip without completely penetrating the whole chip.

2. Description of the Prior Art

Referring now to FIG. 1, a traditional manufacturing method of a semiconductor integrated circuit (IC) comprises the steps of:
(a) providing a semiconductor substrate 01;
(b) forming at least one first unit 02a of a semiconductor element 02 on an active side of the semiconductor substrate 01 of the step (a), wherein the first unit 02a is selected from the group consisting of at least one electrode, at least one ion implantation region, and at least one diffusion unit;
(c) forming at least one second unit 02b on an element layer 03 already superimposed on the semiconductor substrate 01 to constitute a semiconductor element 02, wherein the second unit 02b is selected from the group consisting of at least one other electrode, and at least one other unit;
(d) forming at least one circuit 06 and at least one electrical contact 05 on a dielectric layer 04 already superimposed on the element layer 03 for being electrically connected to the semiconductor element 02 and then to constitute a complete chip 10; and
(e) connecting the electrical contact 05 formed on the chip 10 to at least one other electrical circuit or element (not shown), and then assembling the chip 10 and the electrical circuit or element into a package structure.

Referring back to FIG. 1, the chip 10 manufactured by said traditional manufacturing method has a basic structure provided with electrical circuits, electrical elements and electrical contacts on an active side of the chip 10, and on an inactive side of the chip 10 is only a bare surface of the semiconductor substrate 01 without any electrical contacts, so that the electrical circuits or other electrically conductive paths of the chip 10 do not be electrically connected from the active side to the inactive side.

As a result, the traditional package structure of the chip 10 is electrically connected to at least one other electrical circuit via the active side of the chip 10 only, but the inactive side thereof is never electrically connected to the electrical circuit.

For example, a traditional package structure 08 (i.e. IC) of a single chip 10 (i.e. single die) is illustrated in FIG. 2a, the chip 10 has an inactive side attached to a metal lead-frame 09, and an active side provided with electrical contacts 05 for being electrically connected to the metal lead-frame 09 via bonding wires 07, so that the chip 10 and the metal lead-frame 09 constitute the traditional package structure 08 of the single chip 10.

For example, a flip-chip package structure 08 of a single chip 10 is illustrated in FIG. 2b, the chip 10 has an active side facing toward and mounted on a circuited substrate 11, wherein the active side is provided with electrical contacts 05 for being electrically connected to electrical contacts 11a of the circuited substrate 11 via solder bumps 12.

For example, a traditional System-In-Package (SIP) structure 08 of two chips 10 is illustrated in FIG. 3a, each of the two chips 10 has an inactive side attached to a common circuited substrate 11, and an active side provided with electrical contacts 05 for being electrically connected to electrical contacts 11a of the circuited substrate 11 via bonding wires 07, so that the two chips 10 and the circuited substrate 11 constitute the single SIP structure 08 of the two chips 10. Because the two chips 10 are mounted on the same circuited substrate 11 of the SIP structure 08, the transmission distance between the two chips 10 will be shortened for enhancing the transmission efficiency thereof.

For example, a traditional flip-chip System-In-Package (SIP) structure 08 of two chips 10 is illustrated in FIG. 3b, each of the two chips 10 has an active side provided with electrical contacts 05 for being electrically connected to electrical contacts 11a of the circuited substrate 11 via flip-chip structures, such as solder bumps, so that the two chips 10 and the circuited substrate 11 constitute the single SIP structure 08 of the two chips 10.

For example, a traditional package-in-package (PIP) structure 08 of two chips 10 is illustrated in FIG. 4a. Firstly, one of the two chips 10 is electrically connected to a circuited substrate 11 by bonding wires 07, and encapsulated to form a single package 08a. Then, the other of the two chips 10 is stacked on the package 08a, and electrically connected to the same circuited substrate 11 by other bonding wires 07, so as to constitute the single PIP structure 08 of the two chips 10. Because the two chips 10 are stacked together and mounted on the same circuited substrate 11 of the PIP structure 08, the amount of the circuited substrate 11 in use will be reduced, and the thickness of the circuited substrate 11 and an encapsulant (unlabeled) of the PIP structure 08 will be decreased.

For example, a traditional package structure 08 of two stacked chips 10 is illustrated in FIG. 4b, wherein one of the two chips 10 is a flip chip electrically connected to a circuited substrate 11 by solder bumps. Then, the other of the two chips 10 is stacked on the lower chip 10, and electrically connected to the same circuited substrate 11 by bonding wires 07, so as to constitute the single package structure 08 of the two stacked chips 10, wherein one of the two chips 10 is a flip-chip.

As shown in FIGS. 2a to 4b, the traditional chips 10 used by the various package structures 08 have a common disadvantage, i.e., a bare surface of the chips 10 is not provided with any electrical contact.

Thus, when two chips 10 are assembled into a SIP structure, a PIP structure, or a stacked-die package structure, it needs a circuited substrate to electrically connect the two chips 10 to each other. As a result, the amount of the chips 10 stacked together and the assembled thickness of the package structure 08 will be limited due to the use of the circuited substrate 11. Even though the space and the area of a motherboard (not shown) are limited, the assembled thickness of the package structure 08 still cannot be reduced to fit into the space and the area thereof. The causes of the foregoing shortcomings are described in more details as below:

1. The Stacked Amount of the Chips 10 is Limited:

As shown in FIG. 4a, if the two chips 10 are electrically connected to each other via the circuited substrate 11, an upper surface of the circuited substrate 11 must be provided with enough electrical contacts 11a to electrically connect to the bonding wires 07. However, because the upper surface of the circuited substrate 11 only has a limited area, the amount of the electrical contacts 11a cannot be substantially increased, which subsequently limiting the amount of the chips 10 that can be stacked into the area.

2. The assembled thickness of the package structure 08 cannot be further reduced:

As shown in FIG. 4b, when the two chips 10 are stacked together, the two chips 10 are electrically connected to each other via the bonding wire 07 and the circuited substrate 11. However, the curved height of the bonding wire 07 and the thickness of the circuited substrate 11 cannot be further reduced, so that the assembled thickness of the package structure 08 cannot be minimized.

To solve the foregoing problems of the traditional stacked-die package structure, various technologies for tunneling into semiconductor-processed substrates are further developed.

Referring now to FIG. 5a, U.S. Pat. No. 6,429,096 discloses a chip 10 that is prepared by forming at least one through hole 15 extended from at least one electrical contact 05 on an active side of the chip 10 to an inactive side thereof. Then, filling the through hole 15 with at least one conductive metal 16, so as to form at least one tunneling contact 13.

Therefore, referring now to FIG. 5b, the chip 10 manufactured by U.S. Pat. No. 6,429,096 is formed with the tunneling contact 13 extended from the active side of the chip 10 to the inactive side thereof. As a result, the active side and the inactive side of the chip 10 are respectively provided with at least one electrical contact 05a and at least one electrical contact 05b, both of which are electrically connected to each other via the tunneling contact 13 of the chip 10.

Referring now to FIG. 5c, when at least two of the chips 10 as shown in FIG. 5b are vertically stacked together, the tunneling contacts 13 of the chips 10 are electrically connected in parallel to each other via solder material 12, such as solder bumps. Thereby, a plurality of the chips 10 vertically stacked and electrically connected in parallel are directly assembled on a common circuited substrate 11. Referring now to FIG. 6a, U.S. Pat. No. 6,982,487 discloses a chip 10 that is prepared by forming at least one cavity 15a extended from an active side of the chip 10 into a processed substrate 01. Then, the processed substrate 01 is ground from an inactive side of the chip 10 until the cavity 15a is exposed on the ground inactive side. Finally, an inner wall of the cavity 15a is formed with a deposited conductive metal 16.

Referring now to FIG. 6b, U.S. Pat. No. 6,982,487 further discloses a special carrier 19 that is connected to the chip 10, so as to constitute a chip unit 10a, wherein the chip unit 10a has a first side provided with an electrical contact 05a and a second side provided with an electrical contact 05b.

Referring now to FIG. 6c, when at least two of the chip units 10a as shown in FIG. 6b are vertically stacked together, the electrical contact 05a on the first side of one of the chip units 10a are electrically connected to the electrical contact 05b on the second side of another chip unit 10a via solder material 12, such as solder bumps. Thereby, a plurality of the chip units 10a vertically stacked and electrically connected in parallel are directly assembled on a common circuited substrate 11.

Briefly, the electrical contact 05a of the active side of the chip 10 disclosed in U.S. Pat. No. 6,429,096 can be electrically connected to the electrical contact 05b of the inactive side of the chip 10, and the electrical contact 05a of the first side of the chip unit 10a disclosed in U.S. Pat. No. 6,982,487 can be electrically connected to the electrical contact 05b of the second side of the unit 10a.

However, the manufacturing methods of U.S. Pat. No. 6,429,096 and U.S. Pat. No. 6,982,487 still have common disadvantages, which are described in more details as follows:

1. The Manufacturing Method is Difficult and has a Risk of Damaging the Chip 10:

Both of the U.S. Pat. No. 6,429,096 and 6,982,487 disclose a drilling process after preparing the chip 10. However, the drilling process must drill a conductive layer (unlabeled) and an element layer (unlabeled) of the chip 10, which increases the risk of damaging the chip 10.

2. A Corresponding Region Under the Electrical Contacts 05a on the Active Side of the Chip 10 Cannot be used to Provide Other Circuits 06 or Semiconductor Elements 02:

If the corresponding region under the electrical contacts 05a on the active side of the chip 10 is used to provide other circuits 06 or semiconductor elements 02, the circuits 06 or semiconductor elements 02 of the chip 10 will be damaged during the drilling process after preparing the chip 10 described in both of the U.S. Pat. Nos. 6,429,096 and 6,982,487. In this case, referring now to FIG. 7a, in order to prevent the circuit 06 or semiconductor element 02 of the chip 10 from damaging during the drilling process, the circuit 06 or semiconductor element 02 must be suitably laid-out to stay clear of the electrical contacts 05. However, if there are too many electrical contacts 05, the layout of the circuit 06 or semiconductor element 02 of the chip 10 will become more complicated.

3. The Chips 10 can only be Stacked Together by Electrically Connecting in Parallel to each Other via the Electrical Contacts 05:

Referring to FIG. 7b, because the electrical contacts 05 on the active side of one of the chips 10 is vertically aligned with the electrical contacts 05 on the inactive side of one another of the chips 10, the chips 10 can only be stacked together and electrically connected in parallel to each other via the electrical contacts 05. As a result, the chips 10 cannot be assembled by other methods, and thus the application of the chips 10 is limited.

It is therefore tried by the inventor to develop a novel chip structure and a manufacturing method thereof to solve the problems existing in the traditional chips as described above.

### SUMMARY OF THE INVENTION

A primary object of the present invention is to provide a manufacturing method of a chip structure, wherein before processing the chip, a processed substrate is pre-formed with at least one half-tunneling electrical contact, which completely penetrates or incompletely penetrates the processed substrate, and then the chip is processed, so as to finish the chip with the processed substrate having an inactive side provided with at least one electrical contact of the half-tunneling electrical contact.

A secondary object of the present invention is to provide a chip structure, wherein the chip has a processed substrate with an active side and an inactive side, each of which is provided with at least one electrical contact; the processed substrate is formed with at least one half-tunneling electrical contact penetrating the processed substrate, the half-tunneling electrical contact has a first end exposed on the inactive side of the processed substrate to be an electrical contact of the inactive side thereof, and a second end electrically connected to a circuit formed in the chip.

In one preferred embodiment of the present invention, the electrical contact of the chip can be laid-out on the active side or the inactive side of the chip.

In another preferred embodiment of the present invention, the electrical contact of the chip can also be laid-out over/under an element layer and/or a circuit layer in the chip.

Therefore, the chip of the present invention can provide various layouts and designs of the electrical contacts. Furthermore, the chips can be electrically connected in parallel or in series to each other, so as to be easily stacked together or assembled into a System-In-Package (SIP) structure for the purpose of minimizing the assembled volume thereof.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a cross-sectional view of a traditional manufacturing method of a semiconductor integrated circuit (IC);

FIGS. 2a and 2b are cross-sectional views of traditional package structures of a single chip;

FIGS. 3a and 3b are cross-sectional views of traditional System-In-Package (SIP) structures of two chips;

FIG. 4a is a cross-sectional view of a traditional package-in-package (PIP) structure; FIG. 4b is a cross-sectional view of a traditional package structure of two stacked chips; FIGS. 5a, 5b, and 5c are cross-sectional views of a traditional package structure of stacked chips described in U.S. Pat. No. 6,429,096;

FIGS. 6a, 6b, and 6c are cross-sectional views of a traditional package structure of stacked chip units described in U.S. Pat. No. 6,982,487;

FIGS. 7a and 7b are a top view and a cross-sectional view of a traditional package structure of stacked chips with disadvantages, respectively;

FIGS. 8a, 8b, 8c, and 8d are cross-sectional views of a manufacturing method of a chip structure with at least one half-tunneling electrical contact according to a preferred embodiment of the present invention;

FIG. 9 is a cross-sectional view of a manufacturing method of a chip structure with at least one half-tunneling electrical contact according to another preferred embodiment of the present invention;

FIGS. 10a and 10b are cross-sectional views of a manufacturing method of a chip structure with at least one half-tunneling electrical contact according to another preferred embodiment of the present invention;

FIGS. 11a, 11b, 11c, 11d, 11e, and 11f are cross-sectional views of various layouts and designs of electrical contacts according to another preferred embodiment of the present invention;

FIGS. 12a, 12b, 12c, 12d, and 12e are cross-sectional views of various package structures of a single chip having at least one half-tunneling electrical contact according to another preferred embodiment of the present invention;

FIGS. 13a, 13b, 13c, 13d, and 13e are cross-sectional views of various package structures of stacked chips having at least one half-tunneling electrical contact according to another preferred embodiment of the present invention;

FIGS. 14a, 14b, 14c, 14d, and 14e are cross-sectional views of various System-In-Package (SIP) structures or package structures of stacked chips having at least one half-tunneling electrical contact according to another preferred embodiment of the present invention; and

FIGS. 15a, 15b, and 15c are cross-sectional views of various optical chip structures or microelectromechanical (MEMS) chip structures having at least one half-tunneling electrical contact according to another preferred embodiment of the present invention.

### DETAILED DESCRIPTION OF THE PREFERRED EMBODIMENTS

In the present invention, a chip is fabricated by a semiconductor wafer process. When processing the chip, a semiconductor substrate (i.e. a processed substrate) is pre-formed with at least one electrical contact that is used as an Input/Output terminal after finishing assembling the chip. Because the electrical contact of the present invention only penetrates the processed substrate of the chip without completely penetrating the whole chip (i.e. retaining the other layer of the chip), the electrical contact of the present invention will be called “half-tunneling electrical contact” hereinafter. In the manufacturing method of the chip structure according to the present invention, the processed substrate of the chip is pre-formed with the half-tunneling electrical contact, and then other process steps of the chip are carried out.

The chip structure fabricated by the manufacturing method comprises the processed substrate having at least one of the half-tunneling electrical contact, which penetrates the processed substrate of the chip, wherein the half-tunneling electrical contact has a first end as an electrical contact of an inactive side of the chip, and a second end electrically connected to a circuit layer in the chip.

Referring now to FIG. 8a, a manufacturing method of a chip structure according to a preferred embodiment of the present invention is illustrated, and the manufacturing method comprises the following steps:
(a) providing a semiconductor substrate or processed substrate 01:

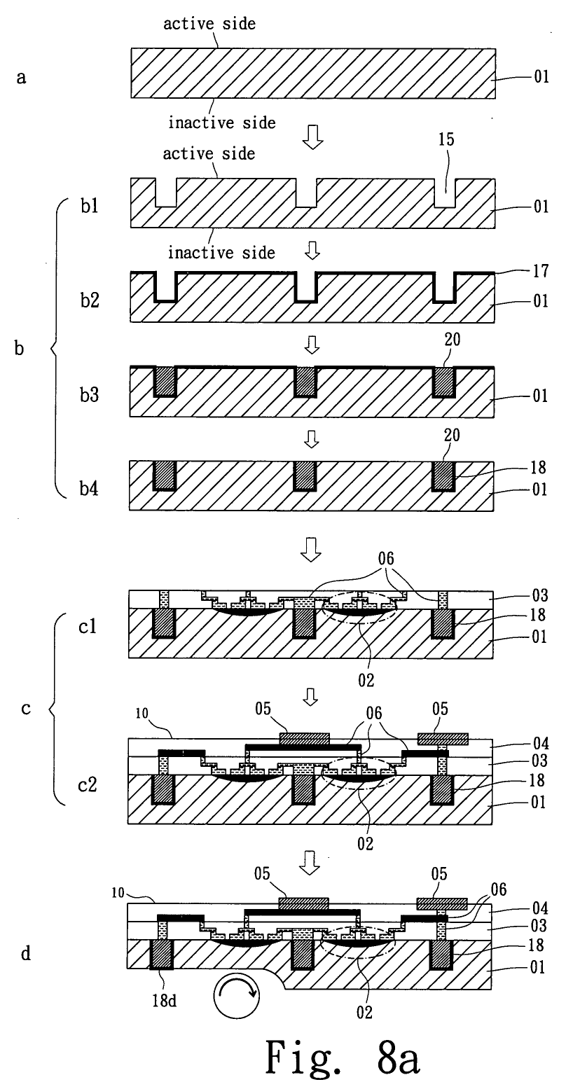

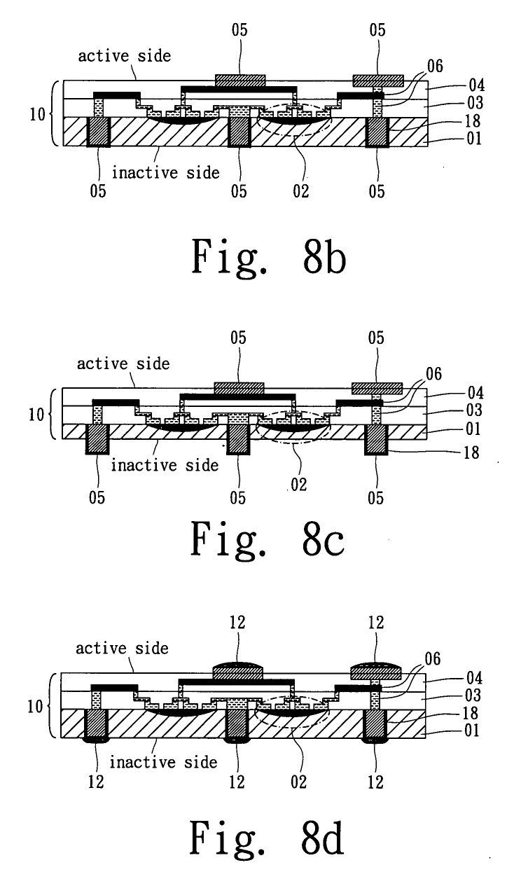

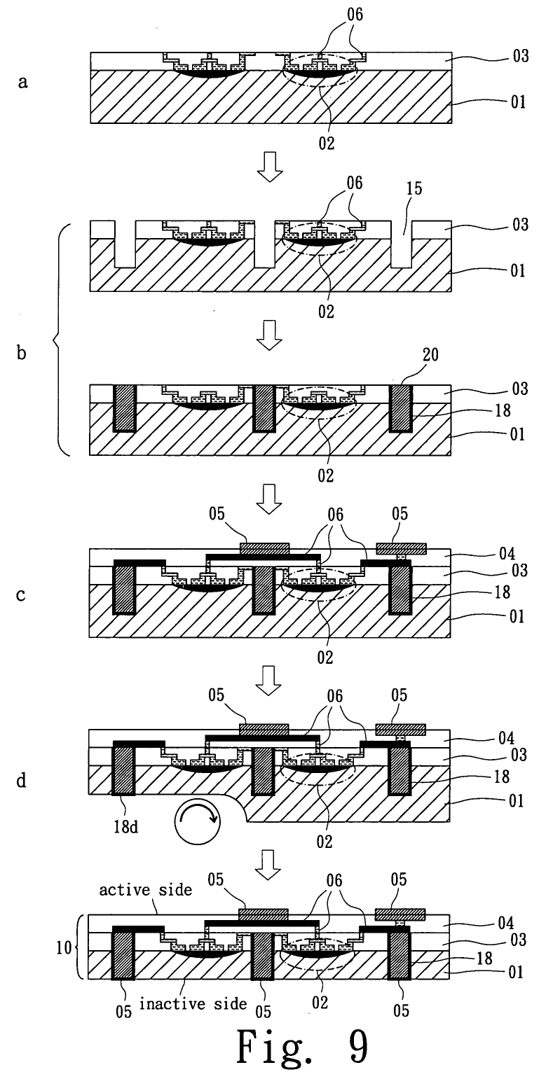

The processed substrate 01 of the present invention is preferably selected from a semiconductor substrate made of single crystal silicon, silica, elements of group 11I, and elements of group V. Moreover, the processed substrate 01 can be selected from a processed substrate 01 without any finishing as shown in FIG. 8a, or a processed substrate 01 partially processed to pre-form at least one semiconductor element 02 as shown in FIG. 9.
(b) forming at least one half-tunneling electrical contact 18 in the processed substrate 01 of the step (a), the step (b) further comprises the following steps:
   (b1) forming at least one cavity 15 on an active side of the processed substrate 01 of the step (a) by semiconductor technologies, such as a semiconductor microlithography and/or an etching technology;

Wherein, the cavity 15 has a horizontal cross section selected from a circular shape, a ring shape, or other shapes. Furthermore, except for the semiconductor microlithography or the etching technology, the cavity 15 can be formed by other manufacturing methods, such as a traditionally mechanical process or a laser process.
(b2) forming at least one pre-formed layer 17, such as a protective layer, an adhesive layer or a seed layer, on a wall surface of the cavity 15 of the step (b1);
(b3) filling a conductive material 20 into the cavity 15 after finishing the step (b2);

Wherein, the conductive material 20 can be selected from the group consisting of nickel, copper, gold, aluminum, tungsten, and alloy thereof. Furthermore, the conductive material 20 can be selected from other conductive metal material or other conductive nonmetal material. The conductive material 20 can be filled into the cavity 15 by a traditional deposition technology, such as physical vapor deposition, chemical vapor deposition, electroplating, or electroless plating (i.e., chemical plating).
(b4) removing a redundant portion of the pre-formed layer 17 (i.e., the protective layer, the adhesive layer, and the seed layer), so that a remaining portion of the conductive material 20 filled in the cavity 15 is defined as the half-tunneling electrical contact 18.
(c) forming at least one semiconductor element 02, at least one related circuit 06, and at least one electrical contact 05 on the active side of the processed substrate 01 after finishing the step (b), and the step (c) further comprises the following steps:
   (c1) forming an element layer 03 on the active side of the processed substrate 01 after finishing the step (b), and then forming the semiconductor element 02 and the related circuit 06 in the element layer 03, wherein the semiconductor element 02 is selected from the group consisting of at least one electrode, at least one ion implantation region, and at least one diffusion unit;
   (c2) forming a dielectric layer 04 on the element layer 03 of the processed substrate 01 after finishing the step (c1), and then forming the other of the circuit 06 in the dielectric layer 04 and forming the electrical contact 05 on the dielectric layer 04.
(d) removing a portion of the inactive side of the processed substrate 01 after finishing the step (c1) until exposing an end 18d of the half-tunneling electrical contact 18 as an electrical contact of the inactive side.

In the step (d) of the present invention, the portion of the inactive side of the processed substrate 01 can be removed by mechanical polishing, chemical polishing, various dry etching, various wet etching, other physical etching, or other chemical etching until exposing the pre-formed end 1 8d of the half-tunneling electrical contact 18.

Referring now to FIG. 9, a manufacturing method of a chip structure according to another preferred embodiment of the present invention is illustrated, wherein when providing a processed substrate 01 in the step (a) of FIG. 9, the processed substrate 01 can be selected from a processed substrate 01 pre-formed with some semiconductor elements 02 as described above, and then is further processed by steps (b), (c), and (d) of FIG. 9 similar to that of FIG. 8a to finish the chip 10.

Therefore, referring now to FIG. 8b, the chip 10 manufactured by the manufacturing method of the present invention is characterized in that the active side and the inactive side of the chip 10 are respectively provided with one or more electrical contacts 05 and one or more half-tunneling electrical contacts 18 penetrated the processed substrate 01, so that the end 1 8d of the half-tunneling electrical contact 18 is exposed on the inactive side of the chip 10 and become an electrical contact 05 formed on the inactive side of the chip 10. Furthermore, the other end of the half-tunneling electrical contact 18 penetrated the processed substrate 01 of the chip 10 is electrically connected to the circuit 06 in the element layer 03 and the dielectric layer 04.

In comparison with FIG. 8b, another embodiment of the present invention is that the other end of the half-tunneling electrical contact 18 of FIG. 9 is penetrated both the processed substrate 01 and the element layer 03 of the chip 10 and is electrically connected to the circuit 06 in the dielectric layer 04.

Furthermore, the electrical contact 05 of the chip 10 can be further processed if necessary. For example, referring now to FIG. 8c, the electrical contact 05 on the inactive side of the chip 10 can be extended out of the processed substrate 01. Alternatively, referring now to FIG. 8d, the electrical contact 05 on the active side and/or the inactive side of the chip 10 can be covered with a solder material 12 for soldering.

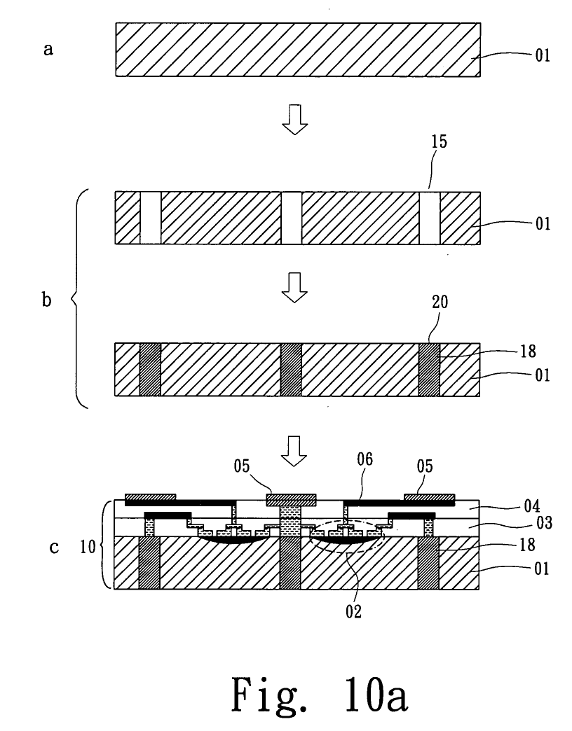

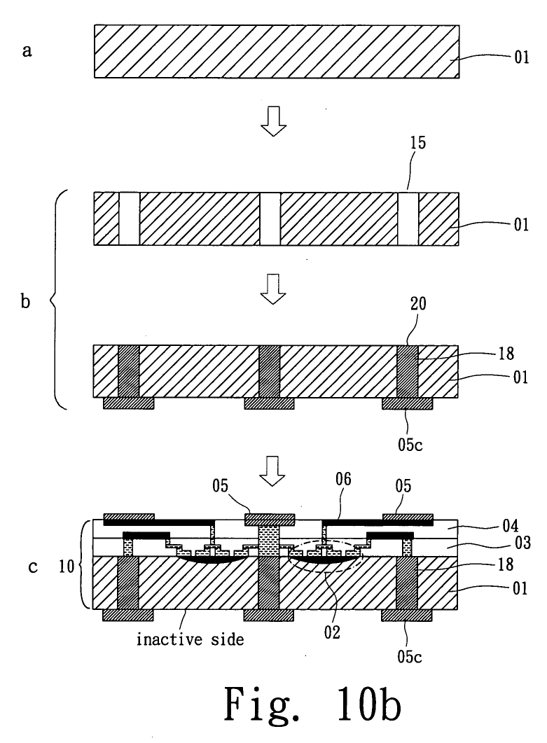

Referring to FIG. 10a, a manufacturing method of a chip structure according to another preferred embodiment of the present invention is illustrated, wherein a step (a) of FIG. 10a is similar to the step (a) of FIG. 8a. In a step (b) of FIG. 10a, when forming a half-tunneling electrical contact 18 in a processed substrate 01, the half-tunneling electrical contact 18 can directly penetrate the processed substrate 01. Then, in a step (c) of FIG. 10a, forming one or more semiconductor elements 02 and/or one or more related circuits 06 and electrical contacts 05 on the active side of the processed substrate 01 to finish the chip 10. In the preferred embodiment of the present invention, the step (d) of FIG. 8a can be omitted. However, in consideration of the thickness of the chip 10, the finished chip 10 of FIG. 10a still can be processed by the step (d) of FIG. 8a for reducing the thickness thereof.

Referring now to FIG. 10b, a manufacturing method of a chip structure according to another preferred embodiment of the present invention is illustrated, wherein a step (a) of FIG. 10b is similar to the step (a) of FIG. 10a. In a step (b) of FIG. 10b, after forming a half-tunneling electrical contact 18 penetrating a processed substrate 01, an end of the half-tunneling electrical contact 18 exposed on an inactive side of the processed substrate 01 can be further pre-formed with an electrical contact 05c or other pre-formed structure. Thus, the finished chip 10 can be provided with the electrical contact 05c on an inactive side of the processed substrate 01.

Referring back to FIG. 8a, in the step (b) of FIG. 8a, one pre-formed layer 17, such as the protective layer, the adhesive layer, or the seed layer, is formed on a wall surface of the cavity 15, the purpose is that the protective layer (i.e., the pre-formed layer 17) can be used to prevent the conductive material 20 from generating an ion diffusion effect with the processed substrate 01 made of single crystal silicon to ensure the electrical property of the conductive material 20. Moreover, the adhesive layer (i.e., the pre-formed layer 17) can be used to improve the adhesive property of the conductive material 20 for preventing the conductive material 20 from separating from the processed substrate 01 made of single crystal silicon. The seed layer (i.e., the pre-formed layer 17) can be used to improve the electrically conductive property of the surface of the cavity 15 for depositing metal of the conductive material 20 on the surface thereof.

Therefore, the material of the pre-formed layer 17, such as the protective layer, the adhesive layer, or the seed layer, is selected according to the material of the conductive material 20. If the conductive material 20 has no shortcomings as described above, the manufacture of the protective layer or the adhesive layer (i.e., the pre-formed layer 17) in the step (b) of FIG. 8a can be omitted.

The structure and the technical means adopted by the present invention to achieve the above and other objects can be best understood by referring to the following detailed description of the preferred embodiments and the accompanying drawings, without limiting the scope of the invention.

Various chip structures in the preferred embodiments are manufactured by the manufacturing method as described above, i.e. each of half-tunneling electrical contacts 18 penetrates a processed substrate 01 of the chip 10, but each of the half-tunneling electrical contacts 18 can be either electrically connected to an electrical contact on an active side of the chip 10 or not electrically connected to the electrical contact.

Furthermore, in one preferred embodiment of the present invention, the electrical contact of the chip can be laid-out on the active side or the inactive side of the chip 10. In another preferred embodiment of the present invention, the electrical contact of the chip 10 can also be laid-out over/under an element layer and/or a circuit layer in the chip 10. Therefore, the chip 10 manufactured by the manufacturing method of the present invention can provide various layouts and designs of the electrical contacts.

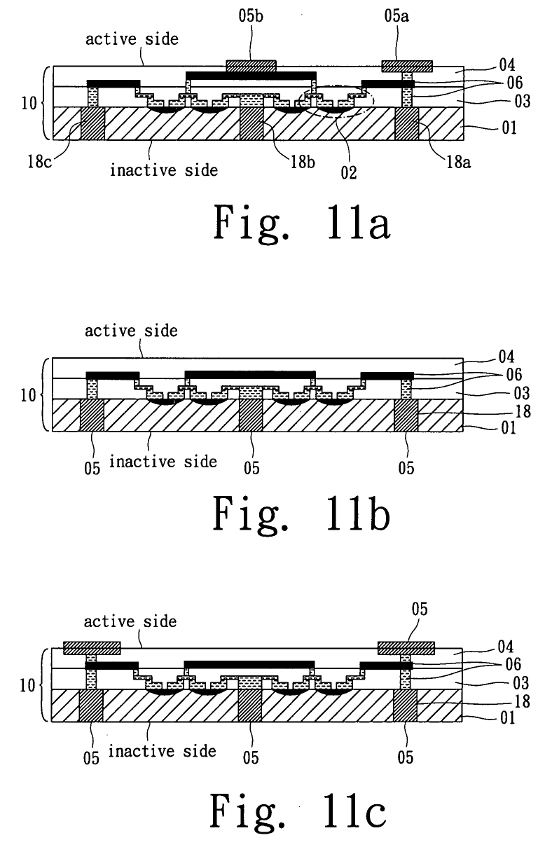

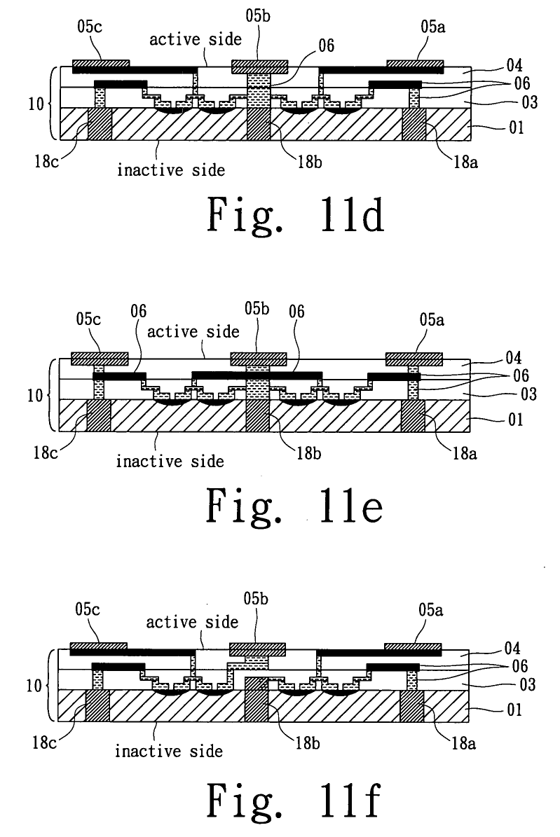

As shown in FIGS. 11a to 11f, six preferred embodiments of the present invention are illustrated to describe various layouts of the electrical contacts of the chip 10 in further details according to various needs.

### First Preferred Embodiment

Referring now to FIG. 11a, the chip 10 of the first preferred embodiment is provided with three half-tunneling electrical contacts 18a, 18b, and 18c, each of which penetrates the processed substrate 01.

Wherein, one end of each of the half-tunneling electrical contacts 18a and 18b is exposed on the inactive side of the processed substrate 01. The other end of the half-tunneling electrical contact 18a is electrically connected to the electrical contact 05a on the active side of the chip 10 via the circuit 06 in the element layer 03 and the dielectric layer 04. Besides, the other end of the half-tunneling electrical contact 18b is electrically connected to the electrical contact 05b on the active side of the chip 10 via the semiconductor element 02 of the element layer 03 and the circuit 06 in the dielectric layer 04.

One end of the half-tunneling electrical contacts 18c is also exposed on the inactive side of the processed substrate 01, but the active side of the chip 10 is not provided with any electrical contact electrically connected to the other end of the half-tunneling electrical contact 18c.

### Second Preferred Embodiment

Referring now to FIG. 11b, the chip 10 of the second preferred embodiment is provided with a plurality of electrical contacts 05, all of which are only exposed on the inactive side of the processed substrate 01.

### Third Preferred Embodiment

Referring now to FIG. 11c, the chip 10 of the third preferred embodiment is provided with a plurality of electrical contacts 05 which are exposed on the active side and the inactive side of the processed substrate 01.

### Fourth Preferred Embodiment

Referring now to FIG. 11d, the chip 10 of the fourth preferred embodiment is provided with three half-tunneling electrical contacts 18a, 18b, and 18c, wherein the half-tunneling electrical contacts 18b is electrically connected to the electrical contact 05b on the active side of the chip 10 and over the half-tunneling electrical contacts 18b via the circuit 06 in the element layer 03 and the dielectric layer 04.

### Fifth Preferred Embodiment

Referring now to FIG. 11e, the chip 10 of the fifth preferred embodiment is provided with three half-tunneling electrical contacts 18a, 18b, and 18c, each of which is electrically connected to the electrical contact 05a, 05b, and 05c on the active side of the chip 10 and over the half-tunneling electrical contacts 18a, 18b, and 18c via the circuit 06 in the element layer 03 and the dielectric layer 04, respectively.

### Sixth Preferred Embodiment

Referring now to FIG. 11f, the chip 10 of the sixth preferred embodiment is provided with three half-tunneling electrical contacts 18a, 18b, and 18c, each of which is not directly connected to the electrical contact 05a, 05b, and 05c on the active side of the chip 10, respectively.

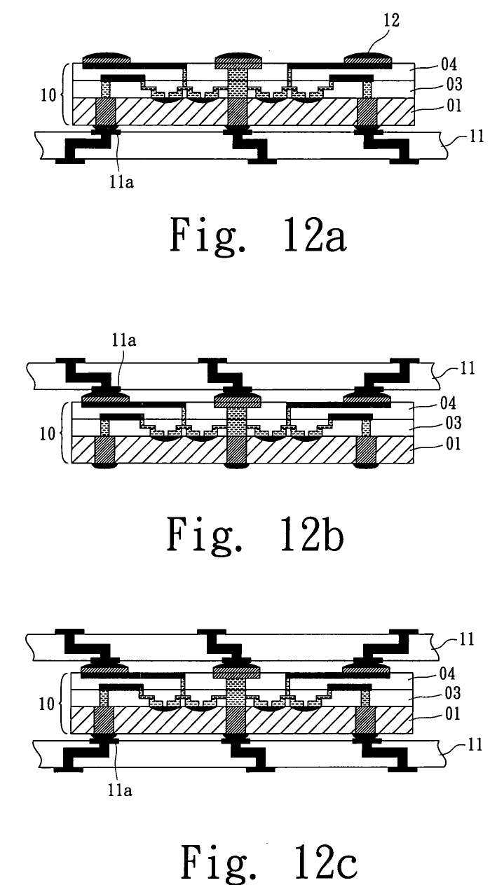

As shown in FIGS. 12a to 12e, five preferred embodiments of the present invention are illustrated to describe various layouts of the electrical contacts of the chip in further details according to various needs, so that the chip of the present invention can provide various electrical connections and be applied to various assembled structures.

### Seventh Preferred Embodiment

Referring now to FIG. 12a, the chip 10 of the seventh preferred embodiment is electrically connected to other element or circuited substrate 11 via the inactive side of the chip 10, so as to finish a package structure.

### Eighth Preferred Embodiment

Referring now to FIG. 12b, the chip 10 of the eighth preferred embodiment is electrically connected to other element or circuited substrate 11 via the active side of the chip 10, so as to finish a package structure.

### Ninth Preferred Embodiment

Referring now to FIG. 12c, the chip 10 of the ninth preferred embodiment is electrically connected to other elements or circuited substrates 11 via the active side and the inactive side of the chip 10, respectively, so as to finish a package structure.

### Tenth Preferred Embodiment

Referring now to FIG. 12d, the chip 10 of the tenth preferred embodiment is electrically connected to other element or circuited substrate 11 via the active side and the inactive side of the chip 10 by different electrical connecting technologies, respectively, so as to finish a package structure.

### Eleventh Preferred Embodiment

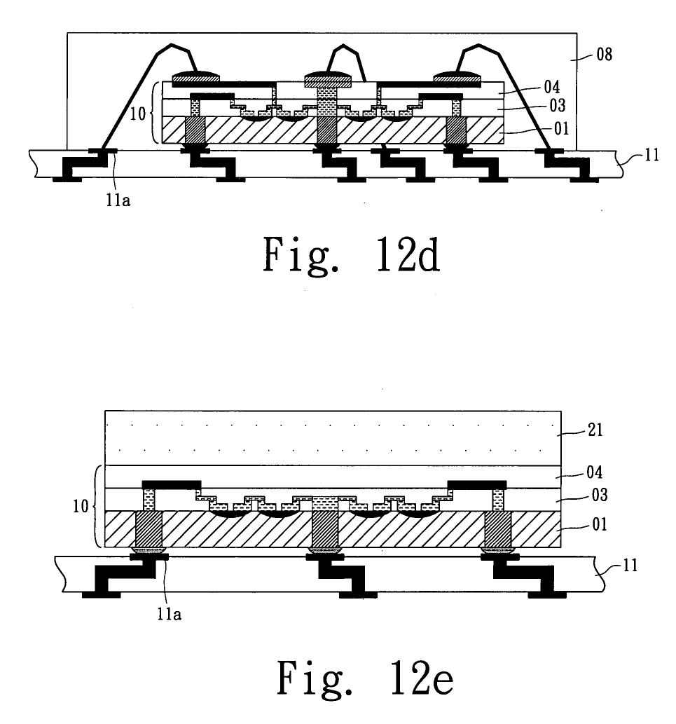

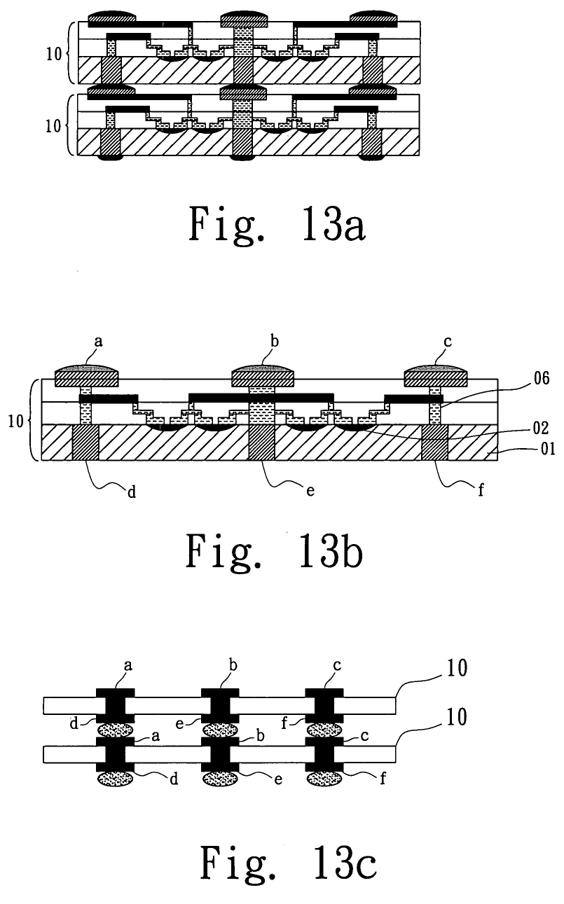

Referring now to FIG. 12e, the chip 10 of the eleventh preferred embodiment is electrically connected to an element 21 and a circuited substrates 11 different from the chip 10 via the active side and the inactive side of the chip 10, respectively, so as to finish a package structure. As shown in FIGS. 13a to 13e, three preferred embodiments of the present invention are illustrated to describe various stacked package structures of the chip in more details according to various needs.

### Twelfth Preferred Embodiment

Referring now to FIG. 13a, a pair of the chips 10 of the twelfth preferred embodiment can be electrically connected to each other via the electrical contacts on the active side and the inactive side thereof, so as to be stacked together.

### Thirteenth Preferred Embodiment

Referring now to FIGS. 13b and 13c, the chip 10 of the thirteenth preferred embodiment is provided with electrical contacts (d), (e), and (f) on the inactive side thereof, wherein the electrical contacts (d), (e), and (f) are correspondingly disposed under the electrical contacts (a), (b), and (c) on the active side of the chip 10, respectively, while the electrical contacts (d), (e), and (f) on the inactive side of the chip 10 are electrically connected to the electrical contacts (a), (b), and (c) on the active side of the chip 10 via the circuits 06 in the chip 10, respectively.

Therefore, referring now to FIG. 13 c, when a pair of the chips 10 are stacked, the electrical contacts (a), (b), and (c) on the active side of the topmost chip 10 can be electrically connected to the electrical contacts (d), (e), and (f) on the inactive side of the lowermost chip 10. In other words, the stacked structure of the two identical chips 10 provides a parallel connection between the two chips 10.

### Fourteenth Preferred Embodiment

Referring now to FIGS. 13d and 13e, the chip 10 of the fourteenth preferred embodiment is provided with electrical contacts (d), (e), and (f) on the inactive side thereof, wherein the electrical contacts (d), (e), and (f) are correspondingly disposed under the electrical contacts (a), (b), and (c) on the active side of the chip 10, respectively, while the electrical contacts (e) on the inactive side of the chip 10 are electrically connected to the electrical contacts (b) on the active side of the chip 10 via the circuit 06 in the chip 10. However, the electrical contacts (d) and (f) on the inactive side of the chip 10 are not directly connected to the electrical contacts (a) and (c) on the active side of the chip 10.

Therefore, referring now to FIG. 13e, when two identical chips 10 are stacked together, the electrical contacts (b) on the active side of the topmost chip 10 can be electrically connected to the electrical contacts (e) on the inactive side of the lowermost chip 10. In other words, the stacked structure of the two identical chips 10 provides a serial connection between the two chips 10.

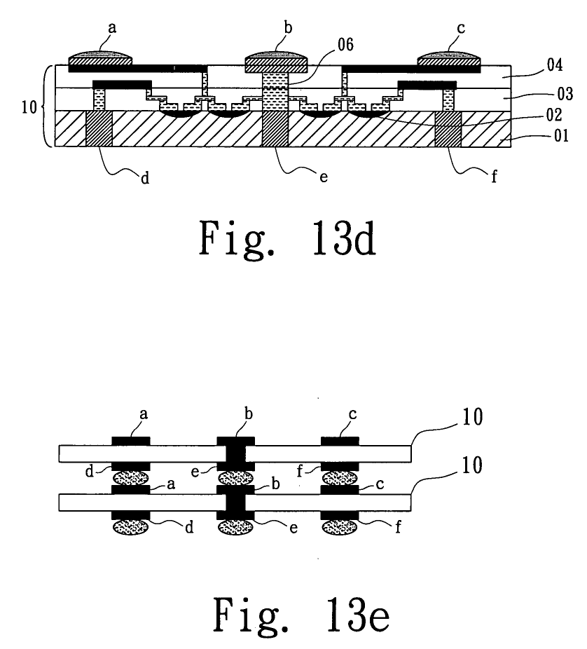

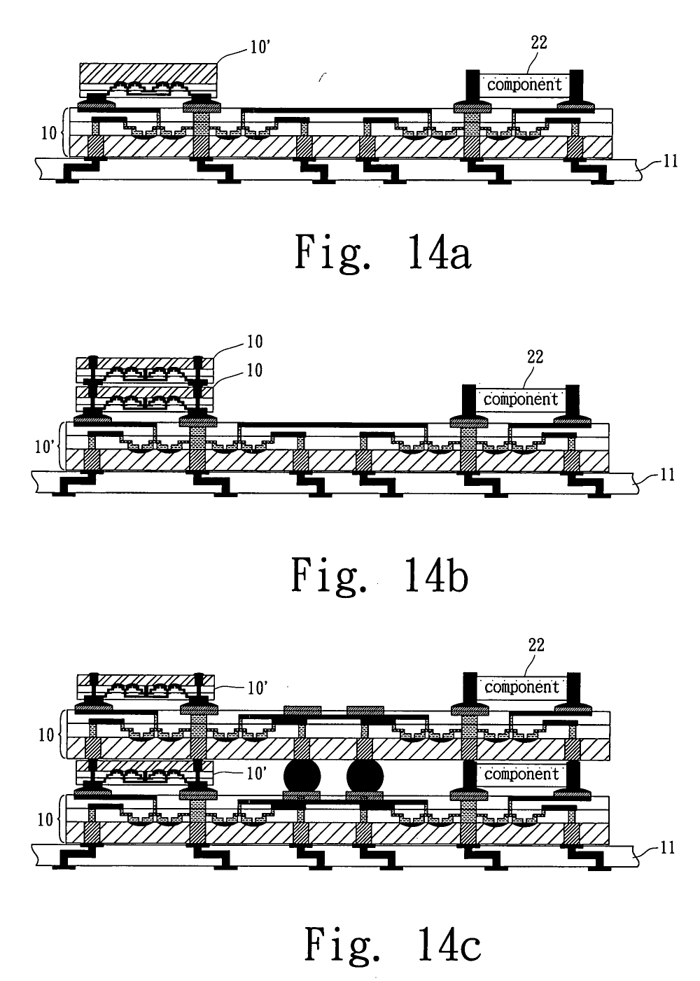

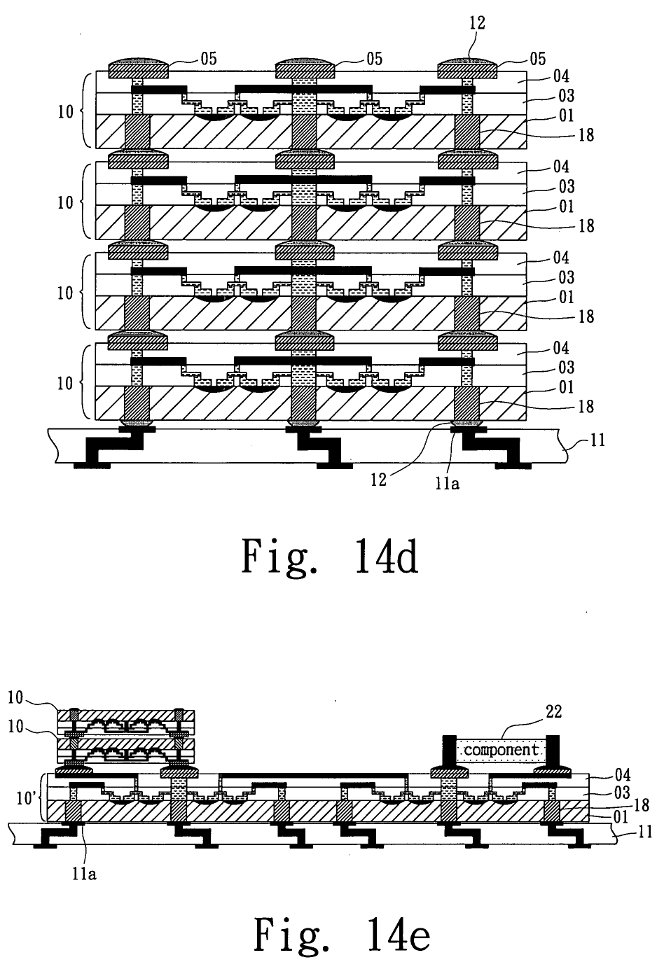

As shown in FIGS. 14a to 14e, five Preferred Embodiments of the present invention are illustrated to describe various System-In-Package (SIP) structures of the chip in more details according to various needs.

### Fifteenth Preferred Embodiment

Referring now to FIG. 14a, the chip 10 of the fifteenth Preferred Embodiment is electrically connected to a chip 10′ or an electronic element 22 different from the chip 10 via the electrical contacts on the active side and the inactive side of the chip 10, respectively, so as to finish a SIP structure.

### Sixteenth Preferred Embodiment

Referring now to FIG. 14b, a pair of the same chips 10 of the sixteenth preferred embodiment are electrically connected to each other via the electrical contacts on the active side and the inactive side of the chips 10, and then the stacked structure of the two chips 10 is electrically connected to a chip 10′ and/or an electronic element 22 different from the chip 10, so as to finish a SIP structure.

### Seventeenth Preferred Embodiment

Referring now to FIG. 14c, the chip 10 of the sixteenth Preferred Embodiment is electrically connected to a different chip 10′ via the electrical contacts on the active side and the inactive side of the chips 10 and 10′, so as to integrate into a stacked unit. The stacked unit of the chips 10 and 10′ can be electrically connected to at least one of the same stacked unit of the chips 10 and 10′, so as to finish a SIP structure with at least two stacked units.

### Eighteenth Preferred Embodiment

Referring now to FIG. 14d, when four of the same chips 10 of the eighteenth Preferred Embodiment are assembled, the four chips 10 are electrically connected to each other via the electrical contacts on the active side and the inactive side of the chips 10, so that the four chips 10 are assembled on a common circuited substrate 11 in a stacked manner.

If the chips 10 of the eighteenth Preferred Embodiment are assembled to constitute a memory IC package, a plurality of memory chips can be integrated into the memory IC package by the stacking method of the eighteenth preferred embodiment, so that the space required by the memory IC package of the memory chips can be substantially minimized.

### Nineteenth Preferred Embodiment

Referring now to FIG. 14e, the two chips 10 of the nineteenth preferred embodiment has an operation function different from that of a chip 10′. When assembling with other different chip or electronic element 22, the two chips 10 are firstly stacked with one on top of the other. Then, the two chips 10 and the other different chip or electronic element 22 are directly stacked on another chip 10′, respectively. Finally, the combination of the two chips 10, the other different chip or electronic element 22, and the chip 10′ is stacked on a common circuited substrate 11, so as to finish a SIP structure.

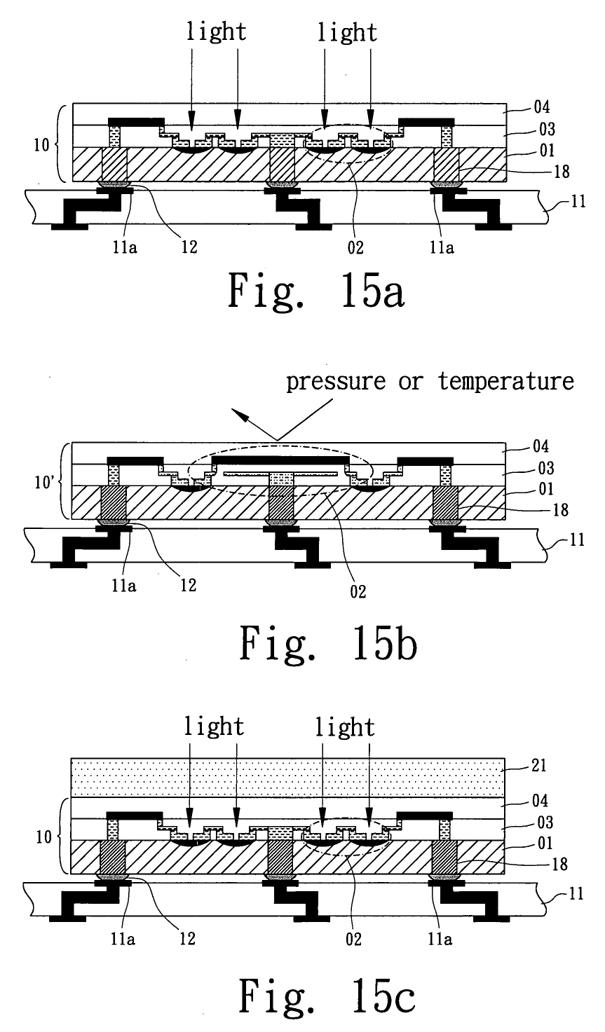

In one preferred embodiment of the present invention, the chips 10 and 10′ are preferably selected from CPU or memory chip, and the electronic element 22 is preferably selected from passive elements, such as resistor or capacitor. In this case, the stacked structure of the nineteenth Preferred Embodiment is advantageous to shorten the transmission distance between the CPU, the memory chip, and the electronic element, so as to increase the variety of the SIP structure. As shown in FIGS. 15a to 15c, two Preferred Embodiments of the present invention are illustrated to describe various semiconductor elements and various package structures of the chip having several special advantages in more details according to various needs.

### Twentieth Preferred Embodiment

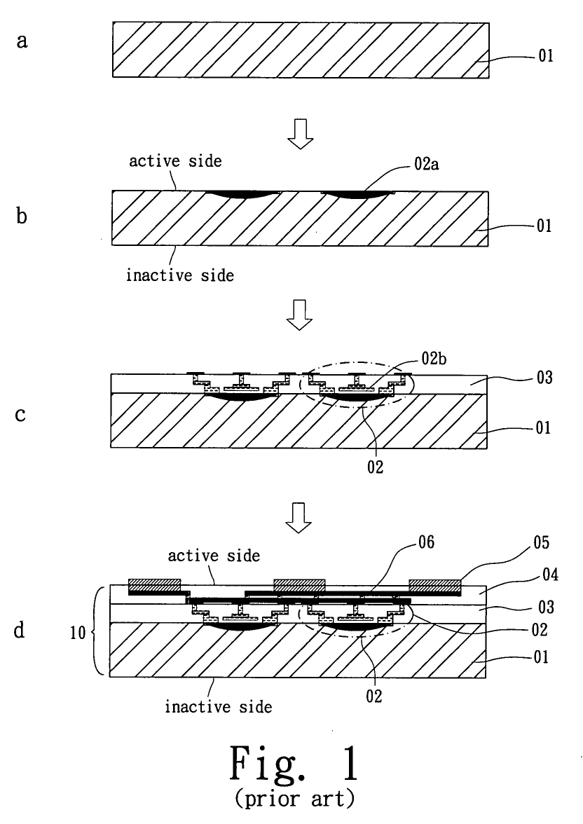

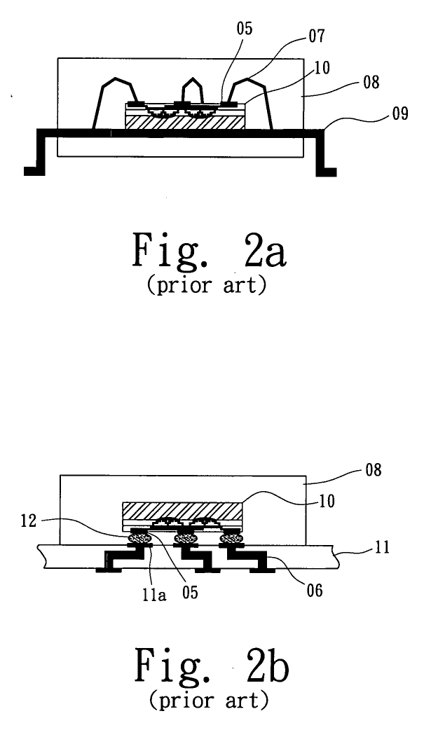

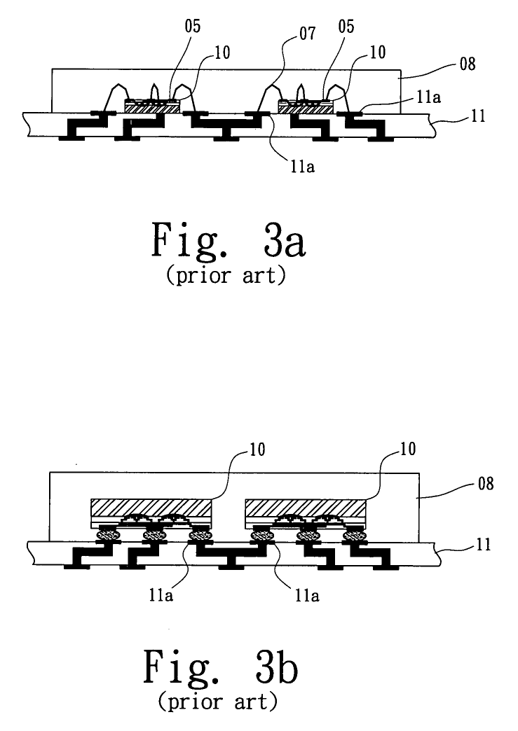

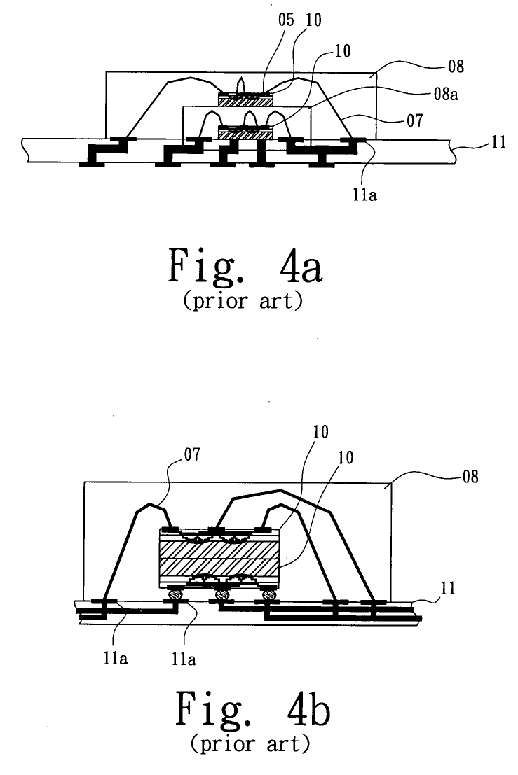

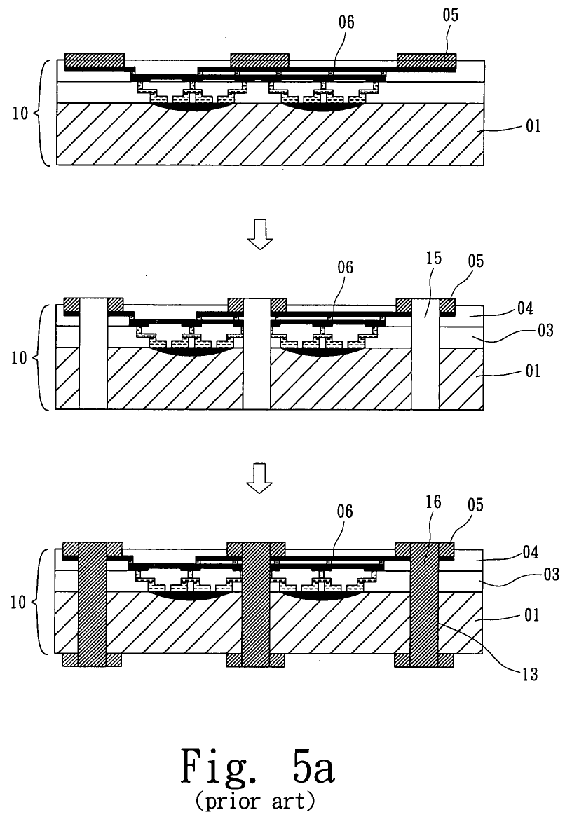

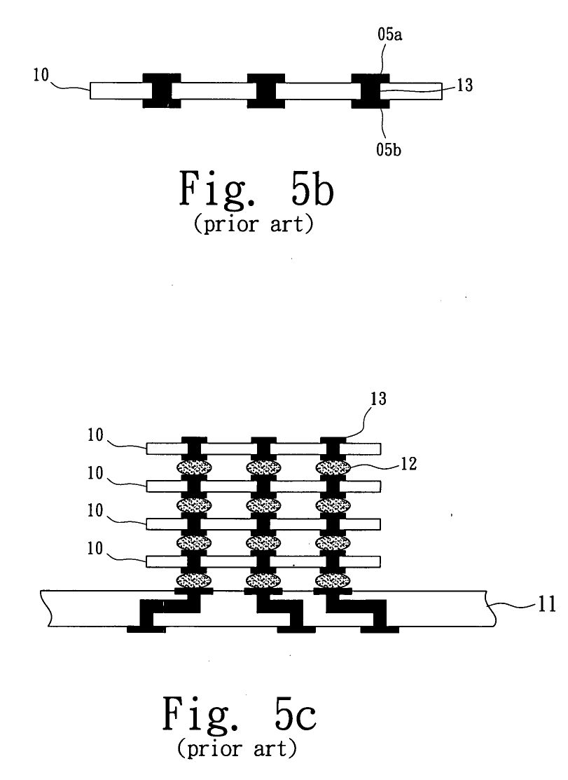

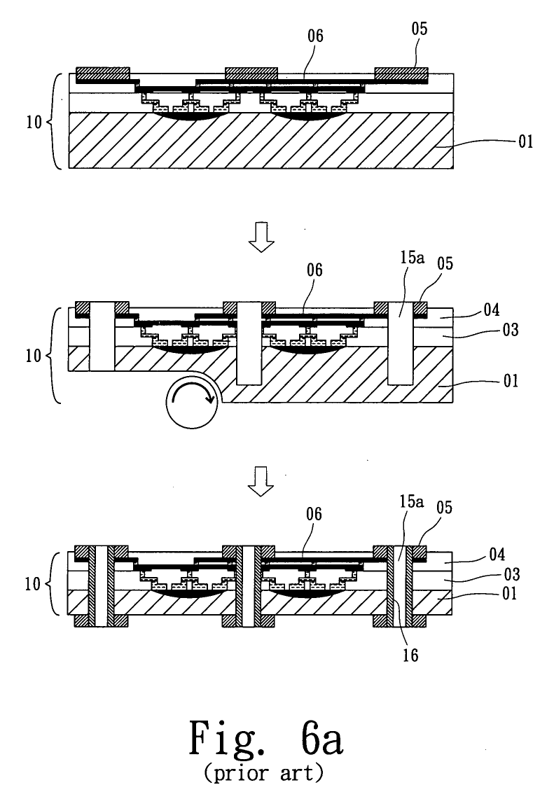

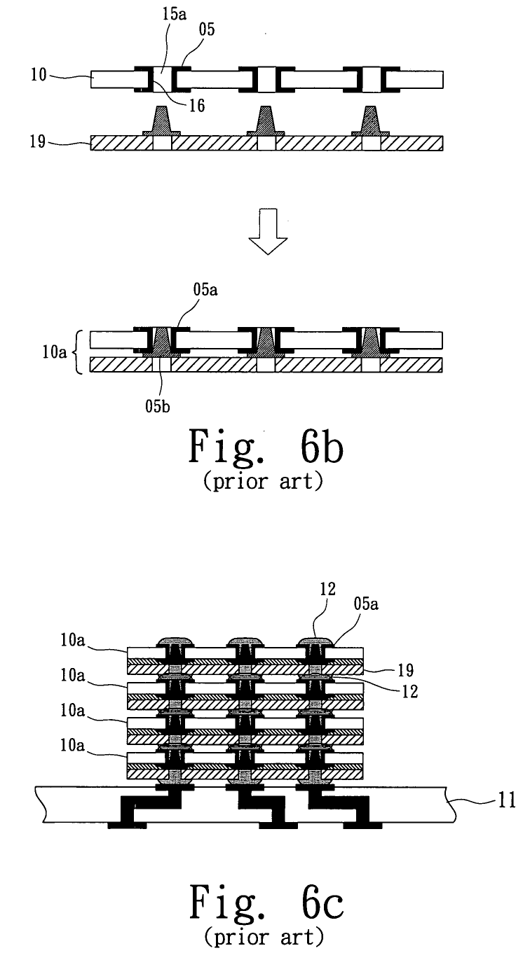

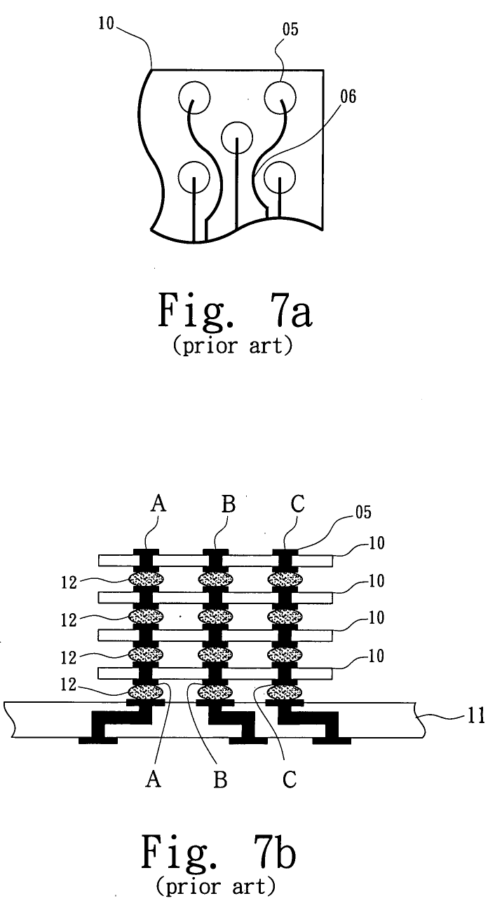

Referring now to FIG. 15a, the chip 10 of the twentieth Preferred Embodiment is selectively provided with an electro-optical element 02; or referring now to FIG. 1 5b, a chip 10′ of the twentieth Preferred Embodiment is selectively provided with a pressure sensor element or temperature sensor element 02a, wherein the chip 10 or 10′ is provided with the half-tunneling electrical contact 18 having an end exposed on the inactive side of the processed substrate 01 for being electrically connected to the electrical contact 11a of the circuited substrate 11 by the solder material 12.

The electrical connection and the package structure in the twentieth preferred embodiment of the present invention is advantageous to prevent an upper surface of the electro-optical element 02 of the chip 10 or the pressure sensor element or temperature sensor element 02a of the chip 10′ from being blocked or hindered by other circuit or substrate,

### Twenty First Preferred Embodiment

Referring now to FIG. 15c, the chip 10 of the twenty-first Preferred Embodiment is provided with the electro-optical element 02, wherein the chip 10 is provided with the half-tunneling electrical contact 18 having an end exposed on the inactive side of the processed substrate 01 for being electrically connected to the electrical contact 11a of the circuited substrate 11 by the solder material 12. Especially, the electro-optical element 02 has an upper surface covered with a transparent material 21, such as glass, so as to protect the electro-optical element 02.

As described above, the chip of the present invention is provided with at least one half-tunneling electrical contact penetrating the processed substrate, while the active side and the inactive side of the chip are respectively provided with at least one electrical contact. The chip structure of the present invention is advantageous to be applied to various package structures, stack-die package structures, and SIP structures.

The present invention has been described with a Preferred Embodiment thereof and it is understood that many changes and modifications to the described embodiment can be carried out without departing from the scope and the spirit of the invention that is intended to be limited only by the appended claims.

What is claimed is:

1. A method for producing a chip structure with one electrical contact formed on inactive side thereof, comprising steps of:
(a) preparing a processed substrate provided with an active side and an inactive side for producing a chip;
(b) forming one or more half-tunneling electrical contacts either completely or incompletely penetrated the processed substrate of the step (a); and
(c) subsequently processing the processed substrate of the step (b) to finish a chip and to have one end of the half-tunneling electrical contact exposed on the inactive side of the processed substrate of the chip.

2. The method for producing a chip structure of claim 1, on the active side of the prepared processed substrate of the step (a) has pre-formed an element layer which has formed one or more semiconductor elements or electric elements thereon.

3. The method for producing a chip structure of claim 1, wherein at step (b) when the half-tunneling electrical contact is incompletely penetrated the processed substrate, further by removing a portion of the inactive side of the processed substrate of the chip until one end of the half-tunneling electrical contact is then exposed.

4. The method for producing a chip structure of claim 2, wherein at step (b) forming one of the half-tunneling electrical contacts is completely penetrated both the processed substrate and the element layer.

5. A chip structure manufactured by the method of claim 1, characterized in that the chip has a processed substrate with an active side and an inactive side and one or more half-tunneling electrical contacts penetrating the processed substrate, wherein each half-tunneling electrical contact has a first end exposed on the inactive side of the processed substrate to be formed as an electrical contact on the inactive side of the chip and a second end exposed on the active side of the processed substrate and electrically connected to a circuit formed inside the chip.

6. The chip structure of claim 5, wherein both the active side and the inactive side of the chip have one or more electrical contacts, and the other end of the half-tunneling electrical contact is directly or not directly formed an electrical connection to the electrical contact formed on the active side of the chip.

7. The chip structure of claim 6, wherein on the active side of the processed substrate has an element layer or a dielectric layer formed thereon, and the other end of the half-tunneling electrical contact is electrically connected to the electrical contact formed on the active side of the chip via either a semiconductor element formed on the element layer or a circuit formed in the dielectric layer or both.

8. The chip structure of claim 7, wherein the location of the electrical contact(s) formed on the inactive side of the chip is correspondingly disposed under that of the electrical contact(s) formed on the active side of the chip.

9. The chip structure of claim 7, wherein the location or the number of the electrical contact(s) formed on the inactive side of the chip is different from that of the electrical contact(s) formed on the active side of the chip.

10. The chip structure of claim 8, wherein two identical chips when stacked together provides a serial connection.

11. The chip structure of claim 6, wherein one or more electronic elements or different chips via the electrical contacts formed on either the active side or the inactive side of the chip to constitute a kind of SIP structure.

12. The chip structure of claim 6, wherein the electrical contact(s) formed on either the inactive side or the active side of the chip is used as an input or output terminal.
